(19) United States
(12) Patent Application Publication
(10) Pub. No.: US 2016/0358783 A1
(43) Pub. Date: Dec. 8, 2016

(54) METHOD AND DEVICE FOR TEXTURING A SILICON SURFACE

(71) Applicant: MEYER BURGER (GERMANY) AG, HOHENSTEIN-ERNSTTHAL (DE)

(72) Inventor: MATTHIAS UHLIG, LUGAU (DE)

(21) Appl. No.: 15/176,390

(22) Filed: Jun. 8, 2016

(30) Foreign Application Priority Data
Jun. 8, 2015 (EP) 15170950.8

(51) Int. Cl. H01L 21/3065; H01L 21/67; H01L 21/677

(52) U.S. Cl. CPC H01L 21/3065; H01L 21/677; H01L 21/67069

(57) ABSTRACT

A method for texturing at least one substrate surface of at least one crystalline silicon substrate includes etching the substrate surface with fluorine gas in a plasma generated in a plasma etching room. A device for texturing at least one substrate surface of at least one crystalline silicon substrate includes a plasma etching room, a gas inlet device coupled with a fluorine source and at least one plasma source. High-quality texturing of silicon surfaces is made possible in a materially and environmentally friendly manner in the method by supplying the plasma etching room with at least gaseous sulfur oxide in addition to the fluorine gas and in the device by additionally coupling the gas inlet device with at least one sulfur oxide source.

### CROSS-REFERENCE TO RELATED APPLICATION

This application claims the priority, under 35 U.S.C. §119, of European Patent Application EP 15170950.8, filed Jun. 8, 2015; the prior application is herewith incorporated by reference in its entirety.

### BACKGROUND OF THE INVENTION

### Field of the Invention

The present invention relates to a method for texturing at least one substrate surface of at least one crystalline silicon substrate by etching the substrate surface with fluorine gas in a plasma generated in a plasma etching room. The present invention further relates to a device for texturing at least one substrate surface of at least one crystalline silicon substrate by using a plasma etching room having a gas inlet device coupled with a fluorine source and at least one plasma source.

In this context, texturing means to produce a high, but even surface roughness of the substrate surface in the micrometer and submicrometer range. Such a textured surface absorbs more and reflects less electromagnetic radiation than a smooth surface. Hence, such texturing is provided at surfaces, at which electromagnetic radiation shall interact with the material under the surface, for instance, in a photovoltaic cell. When a surface of that cell is textured, less light is reflected and the degree of efficiency of the photovoltaic cell increases in comparison to a cell having a surface which is not textured. For texturing, mainly fluorine-containing chemicals are used in order to transform silicon and, for instance, silicon oxide inter alia to volatile silicon tetrafluoride. Due to the high reactivity, and connected thereto, high security demands in terms of the fluorine gas, its industrial use as a process gas is subject to strict conditions. Particularly, the transport of fluorine gas is severely limited. Thus, for texturing silicon substrates, fluorine-containing process gases such as sulfur hexafluoride, nitrogen trifluoride or tetrafluoromethane are often used.

An initially mentioned method as well as an initially mentioned device are known from International Publication WO 2009/092453 A2, corresponding to U.S. Patent Application Publication US 2010/0288330. In that document, a plasma etching process for silicon surfaces is described, which is executable with fluorine gas, carbonyl fluoride or nitrogen trifluoride or a mixture thereof. Furthermore, it is suggested that, for instance, sulfur hexafluoride be additionally added to the etching gas. The usage of sulfur hexafluoride and nitrogen trifluoride is disadvantageous because of their effect as greenhouse gases.

International Publication WO 2012/145473 A1 discloses a dry etching process with fluorine gas for the etching and texturing of a silicon wafer surface. In that process, 7 to 20 μm of the surface of a silicon wafer are removed at a temperature of 450 to 550° C. and a pressure of 10 to 50 torr in a period of 30 to 90 seconds, wherein saw damages are removed and a texturing of the surface is provided. A so-called “dark texture” is thereby produced, which absorbs light even more effectively than is possible for textures produced by wet chemical dip-methods. Due to the high etching rate, the process described is only poorly controllable.

Another known method is described in U.S. Patent Application Publication US 2013/0069204 A1. There, fluorine gas or fluorine-containing gas such as tetrafluoromethane, trifluoromethane, carbonyl fluoride, sulfur hexafluoride, nitrogen trifluoride or xenon difluoride is used in a mixture with a chlorinated compound for etching and structuring a surface of a silicon wafer at temperatures of more than 450° C. Tetrachloromethane, trichlorosilane with hydrogen or hydrogen chloride are used as chlorinated compounds. The fluorine-containing as well as chlorinated process exhaust gases are only disposable with great technical effort.

U.S. Pat. No. 8,952,949 B2 discloses a plasma etching process for texturing a silicon surface, in which a mixture of sulfur hexafluoride and oxygen is used in a high-frequency plasma. In that case, too, the usage of sulfur hexafluoride is disadvantageous because of the strong greenhouse gas effect.

Furthermore, U.S. Patent Application Publication US 2014/0216541 A1 suggests a multi-staged method for texturing a silicon surface, at which a wet-chemical, alkaline etching process for generating a surface being formed by pyramids is initially provided. Subsequently, a further fine texturing by dry etching with chlorine trifluoride is performed. Such multi-staged methods are time and material consuming since a complex drying has to follow the wet chemical process stage in order to avoid interferences during the dry etching process. In that case, the production of extensive chemical waste and the long process duration are disadvantageous.

### SUMMARY OF THE INVENTION

It is accordingly an object of the invention to provide a method and a device for texturing a silicon surface, which overcome the hereinafore-mentioned disadvantages of the heretofore-known methods and devices of this general type and in which a high-quality texturing of silicon surfaces is possible in a materially and environmentally friendly manner.

With the foregoing and other objects in view there is provided, in accordance with the invention, a method for texturing at least one substrate surface of at least one crystalline silicon substrate by etching the substrate surface with fluorine gas, which comprises etching the silicon substrate in a plasma, which is produced in a plasma etching room and supplying the plasma etching room with at least gaseous sulfur oxide besides fluorine gas. In this case and in the following, sulfur oxides are termed compounds of the general formula SₓO_{y}, for instance, disulfur monoxide, sulfur monoxide, sulfur dioxide, disulfur dioxide and/or sulfur trioxide.

The usage of fluorine gas in a plasma is advantageous since the reaction chemistry in the fluorine-based plasma process is adjustable over a wide range. Known methods in the state of the art result in either smooth substrate surfaces, which include very high reflectivities, or in so-called “dark textures,” which reflect very little electromagnetic radiation but which also absorb a large part of the radiation within the textured surface instead of respectively guiding this radiation to a bulk region of the substrate or to a pn-junction located in the silicon substrate. Moreover, “dark textures” are very fragile and thus hard to passivate in a coating process. For this reason, the substrate surfaces textured this way are not suitable for usage, for example, in solar cells. For the method according to the invention, a particularly advantageous texturing of the substrate surface has evolved surprisingly, when sulfur oxide, SₓO_{y}, is added to the fluorine gas in the plasma etching room.

According to the invention, gaseous sulfur oxide is used in addition to fluorine gas for a plasma etching process for texturing silicon surfaces, thus a plasma-excited chemical etching process of silicon surfaces is realized. The application of the plasma leads to the formation of radicals and reactive ions as well as atoms and molecules in excited states, which can react with the silicon surface as well as with possibly present air oxide, that is silicon oxide being at the substrate surface, or with oxygenic compounds such as O₂ or N₂O additionally added to the process gas. This allows the treatment of the most varied silicon substrates since the process is therefore, in contrast to pure physical or pure chemical machining processes, independent from, for instance, crystallographic characteristics of the substrate surface to be treated or from the substrate production method being used. Thereby, wafers cut by diamond wire can be textured as well as very thin silicon substrates, for instance. When using reactive ion etching, also called RIE, however, radicals and reactive ions as well as atoms and molecules in excited states are accelerated towards the substrate surface by a potential gradient, whereby these particles hit the substrate surface at high speed and physically knock atoms out of the substrate surface. Thereby, tensions in the crystal of the silicon substrate can be evoked. This is avoided by the method according to the invention.

In contrast to wet chemical texturing methods, a one-side process is realizable by the method according to the invention, which only textures a silicon substrate at a desired surface. Thus, fewer chemicals than in a wet chemical texturing process are used by this method. No deionized water, which is used in wet chemical etching methods for substrate flushing, has to be reprocessed. Moreover, a subsequent polishing of the back side of the silicon substrate is not applied in the present invention as is necessary or which is at least advantageous in various production technologies particularly for high-efficiency solar cells. With wet chemical methods, the resulting waste products are in solution and thus stay a long time near the substrate surface. The increasing concentration of the products as well as the decreasing concentration of the etching reagents in the etching bath during the process duration lead to a slowing of the texturing process, whereby with wet chemical methods, the etching baths being used have to be regularly changed or at least replenished and the reprocessing of the used etching baths involves great effort. In contrast, when using the method according to the invention, the resulting waste products are gaseous and in process are quickly removed from the substrate surface by a gas outlet. Simultaneously, new etching, process and auxiliary gases can be added constantly to the plasma etching room. Hence, on one hand, the reaction speed of the texturing method according to the invention is independent of the process duration and, on the other hand, much less waste to be reprocessed results than when using wet chemical texturing methods. Moreover, an accumulation of impurities in the process room is greatly reduced in the present invention.

With the method according to the invention, gases are used, which have very little or no greenhouse effect and which can be easily separated from the process exhaust gases. The exhaust gases to be separated in the method of the invention such as silicon tetrafluoride, fluorine gas, oxygen difluoride or hydrogen fluoride are environmentally neutral or at least neutral with regard to climate warming. Furthermore, the method according to the invention makes it possible to discharge very little to no environmentally harmful exhaust gases into the environment. Moreover, according to the invention, the use of chemicals is substantially reduced as compared to methods which use other process gases, since, for instance, the atom efficiency of the fluorine gas being used is 80% to 90% in this method.

In a further development of the method according to the invention, it is provided that the fluorine gas is generated by electrolysis in at least one fluorine gas generating system being coupled with the plasma etching room and then led into the plasma etching room. Thus, a production of the fluorine gas at the place of the plasma etching process is provided, whereby, on one hand, the transport of fluorine is omitted and, on the other hand, the fluorine gas according to the process requirements is always provided in the required quantity. As a precursor for the fluorine production in the fluorine gas generating system, hydrogen fluoride is used, which can be transported safely and first of all without loss to the place where the texturing is carried out. Furthermore, hydrogen fluoride, from which the fluorine gas is producible in the fluorine gas generating system, is a liquid under corresponding pressure and/or under corresponding cooling which is storable and transportable in a much more space-saving manner than fluorine gas.

During the electrolysis, fluorine gas normally forms at atmospheric pressure. Hence, in order to produce a higher pressure it is of advantage if at least one pressure raising device is provided between the fluorine gas generating system and the plasma etching room. The pressure raising device can be followed by a separate pressure vessel, in which the generated fluorine gas can be temporarily stored under pressure. The pressure to be reached for the fluorine gas in such a pressure vessel is preferably in a range from 1 bar to 3.5 bar overpressure. The pressure in the plasma etching room is lower than the atmospheric pressure, preferably lower than 100 mbar, particularly preferably lower than 10 mbar. In order to accordingly reduce the pressure of the fluorine gas from the pressure vessel or directly from the fluorine source to the plasma etching room, at least one pressure reducing valve and/or a mass flow controller can be provided in a corresponding gas line between the fluorine source and the plasma etching room. At least one corresponding pressure reducing valve and/or a mass flow controller can also be provided in the gas line between the sulfur oxide source and the plasma etching room. Should further gases from other gas sources be led into the plasma etching room, at least one pressure reducing valve and/or a mass flow controller can also be provided in the gas line between the gas source and the plasma etching room.

It is of further advantage if the fluorine gas is led into the plasma etching room more closely to the substrate surface than the other process gases used in the method, for instance, the sulfur oxide. Thereby, it is guaranteed that the particularly reactive fluorine gas has to pass over a possibly shorter distance to the substrate surface to be textured. Or else, there might be side reactions of the fluorine gas with other gases used for the plasma, for instance, with the sulfur oxide, which could negatively influence the atom efficiency of the fluorine gas being used. The sulfur oxide and possibly further auxiliary gases being used are introduced into the plasma etching room further away from the substrate surface than the fluorine gas, where they can respectively mix in the plasma with the fluorine gas or the fluorine species.

In a further advantageous embodiment of the method according to the invention, unused process gases from etching and exhaust gases resulting from the etching are led out of the plasma through at least one gas outlet and subsequently led through at least one wet chemical exhaust gas treatment device. In the wet chemical exhaust gas treatment device, etching gases not used in the method of the invention such as fluorine and at least sulfur oxide, but also gases resulting from the reaction such as silicon tetrafluoride, hydrogen fluoride and/or oxygen difluoride can be adsorbed and/or absorbed. For instance, an exhaust gas treatment device can be provided as a washer in order to absorb the gases in solution and/or to chemically transform them. Toxic and/or acidic reacting substances can thereby be washed out from the exhaust gases. The acidic residues possibly resulting in the exhaust gas treatment device such as hydrogen fluoride acid, also called hydrofluoric acid, can be subsequently transformed into ecologically friendly waste by neutralization with at least one base.

Preferably, the plasma of the method according to the invention is generated at a frequency in the microwave range or by at least one inductively coupled plasma source, also called an ICP source. The usage of microwave plasma sources or ICP sources has the advantage that there is substantially no acceleration of ions and/or radicals by using a potential difference in the direction of the substrate surface, which is to say substantially no physical etching of the substrate surface and a thereby induced crystal damage of the silicon substrate at the substrate surface. A crystal tension, for instance, of the textured substrate can thereby be largely prevented. In an alternative embodiment, the generation of a plasma in the high frequency range is also possible.

In another preferred embodiment of the method according to the invention, the silicon substrates are heated and/or cooled by a substrate tempering device in the plasma etching room. In this way, for instance, a reaction temperature for the texturing process of less than 200° C., preferably of less than 150° C., particularly preferably of less than 100° C. can be provided at the substrate surface in the plasma. The selectivity of the texturing method can thereby be increased in contrast to a mainly corrosive material abrasion.

In a particularly advantageous embodiment of the method according to the invention, silicon substrates are continuously passed on a substrate transport device through the plasma etching room. Hence, an installation, in which the method is operable, is continuously equipped with silicon wafers, which enables a timely and energetically more efficient mode of operation than a so-called “batch-method.”

With the objects of the invention in view, there is also provided a device for texturing at least one substrate surface of at least one crystalline silicon substrate by using a plasma etching room, the device comprising a gas inlet device, which is coupled to a fluorine source, and at least one plasma source. The gas inlet device is additionally coupled with at least one sulfur oxide source. Sulfur oxides in this case and in the following include compounds of the general formula SₓO_{y} such as disulfur monoxide, sulfur monoxide, sulfur dioxide, disulfur dioxide and/or sulfur trioxide.

Through the use of the fluorine gas source, fluorine gas can be added to the plasma, with which silicon with a very precisely adjustable etching rate can be etched. In contrast to devices known from the state of the art, the gas inlet device of the device according to the invention is not only coupled with a fluorine source but also with a sulfur oxide source.

Hence, in the device according to the invention, gaseous sulfur oxide and fluorine gas for a plasma etching process for texturing silicon surfaces can be led into the plasma etching room. Thus, in the device according to the invention, a plasma-excited chemical etching process for texturing silicon surfaces can be provided. In the plasma producible in the plasma etching room, radicals, reactive ions as well as atoms and molecules in excited states are generated from the gases added, which can react with the silicon surface and with silicon oxide possibly present or produced thereon. This allows the treatment of the most varied silicon substrates since in contrast to physical or pure etching devices, silicon substrates can be textured independent from, for instance, crystallographic characteristics of the substrate surface to be treated or from the substrate production method being used. In the device according to the invention, wafer cutting by diamond wire as well as very thin silicon substrates can be textured advantageously on one or on both sides. The device according to the invention makes it possible to provide a gentle surface etching and structuring of the silicon surface in contrast to RIE (reactive ion etching) etching devices known from the state of the art, whereby, for instance, crystal tensions or the like can be avoided.

In contrast to devices, which are provided for wet chemical texturing, in the device according to the invention, a one side process can also be realized, at which a silicon substrate is only textured at one desired surface. Thus, by using the device according to the invention, fewer chemicals are needed than when using devices, which are used for wet chemical texturing processes. When using the device according to the invention, the known reprocessing of contaminated deionized water at wet chemical etching devices is omitted. Furthermore, a subsequent polishing of the back side of the silicon substrate, when using the device according to the invention, is not necessary. The chemical waste products resulting from the device according to the invention are gaseous and can be discharged well from the substrate surface by at least one gas outlet of the device. Simultaneously, new etching, process and/or auxiliary gases can be continuously added to the plasma etching room. Thus, on one hand, in the device of the invention, the reaction rate is independent of the process duration and, on the other hand, much less waste to be reprocessed is generated in comparison to wet chemical texturing.

With the device according to the invention, gases are addable to the etching room, which have very little or no greenhouse effect and which can be easily separated from the process exhaust gases. The exhaust gases to be separated in the device according to the invention such as silicon tetrafluoride, fluorine gas, oxygen difluoride and/or hydrogen fluoride are environmentally neutral or transferable to environmental neutral compounds in the exhaust gas treatment or at least neutral with regard to the climate warming. Furthermore, the device according to the invention makes it possible to discharge only very little to no environmentally harmful exhaust gases into the environment. Moreover, the use of chemicals is substantially reduced as compared to devices, in which wet chemical texturing is operable as well as compared to devices, in which other process gases are used, since, for instance, the chemical transfer efficiency of the fluorine gas being used is 80% to 90% in this device.

According to an advantageous embodiment of the device according to the invention, the fluorine source is a fluorine gas supply system and/or fluorine gas generating system coupled with the plasma etching room, in which the fluorine, before being led into the etching room, is producible by electrolysis from hydrogen fluoride. Thus, it is possible to directly generate fluorine gas at the texturing device, so that a transport and/or a storage of fluorine gas is/are not necessary. Instead, hydrogen fluoride, from which the fluorine gas is producible in the fluorine gas generating system, is storable as a liquid under corresponding pressure and/or under corresponding cooling in a much more space-saving manner than fluorine gas. Moreover, by using this embodiment of the invention, the supply of fluorine gas can be made accordingly in dependence on the gas requirement of the texturing process.

In an advantageous embodiment of the device according to the invention, at least one cleaning module and/or a pressure raising device is/are provided between the fluorine gas generating system and the plasma etching room. The fluorine gas, which is generated by the electrolysis in the fluorine gas generating system, can normally still contain hydrogen fluoride. Hence, the transmission of the gas mixture produced in the fluorine generating system through a cleaning module is advantageous, in which hydrogen fluoride and possibly other impurities can be removed so that fluorine gas of high purity can be led into the plasma etching room. Furthermore, the gas mixture flows typically under atmospheric pressure from the fluorine gas generating system to the plasma etching room. In order to reach a higher pressure than atmospheric pressure, the usage of a pressure raising device between the fluorine gas generating system and the plasma etching room is of advantage. Such a pressure raising device can be provided in a possible embodiment, for instance, in form of a compressor and a pressure vessel, which is used as a supply for compressed fluorine gas.

In an alternative embodiment of the present invention, the fluorine source can also be provided in the form of at least one compressed gas cylinder. In this case, a cleaning module and/or a pressure raising step can be dispensed with. In this case, the compressed gas cylinder is used as a fluorine source as well as a pressure vessel.

In each of these embodiments, it is of advantage, if at least a pressure reducing valve and/or a mass flow controller is/are provided between the fluorine source and the plasma etching room. This makes it respectively possible to adjust the pressure of the fluorine gas to the pressure of the plasma etching room, where preferably a pressure of less than 100 mbar, particularly preferably of less than 10 mbar predominates or to adjust a defined gas flow. At least a corresponding pressure reducing valve and/or a mass flow controller is/are preferably provided also in the gas line between the sulfur oxide source and the plasma etching room. Should further gases from other gas sources be led into the plasma etching room, at least a pressure reducing valve and/or a mass flow controller is/are always preferably correspondingly provided there in the gas line between the gas source and the plasma etching room.

In a particularly preferred embodiment of the present invention, a gas inlet of the gas inlet device being connected with the fluorine source is provided more closely to the substrate surface than a gas inlet of the gas inlet device connected with the sulfur oxide source. The gas inlets are preferably provided above the substrate transport device in the plasma etching room. In a preferred embodiment of the invention, the at least two gas inlets, which are at least used for the inlet of fluorine gas and sulfur oxide, are disposed vertically in various heights, that is, there is at least an upper and a lower gas inlet, wherein the upper gas inlet being connected with the sulfur oxide source is disposed farther from the substrate surface than the lower gas inlet being connected with the fluorine source. Thus, fluorine gas is introducible into the plasma etching room in particular proximity to the substrate surface, while sulfur oxide and further process and/or auxiliary gases depending on the embodiment are introducible into the plasma etching room at a greater distance from the substrate surface than fluorine gas.

In an advantageous embodiment of the device according to the invention, the plasma etching room includes at least one gas outlet, which leads to at least one wet chemical exhaust gas treatment device. The exhaust gas treatment device is used for adsorption and/or absorption of toxic and/or acidic reacting which is not used and/or resulting gases of the device according to the invention by using wet chemical processes. These gases include mainly fluorine gas, silicon tetrafluoride, oxygen difluoride, sulfur dioxide or hydrogen fluoride. In an advantageous embodiment of the invention, the exhaust gas treatment device may include a washer and if necessary a burner, in which the gases are absorbed and/or chemically converted in solution. In such a washer, hydrofluoric acid, also known as hydrogen fluoride, for instance, can be provided from fluoride-containing materials in the exhaust, which can be neutralized subsequently in the exhaust gas treatment device by at least one base thus resulting in harmless waste.

In another embodiment of the device according to the invention, the at least one plasma source is provided as a microwave plasma source and/or as an inductively coupled plasma source or so-called ICP source. The plasma allows the processing of the most varied silicon substrates, the process is independent from, for instance, crystallographic characteristics of the substrate surface to be treated or from the substrate generating process being used. Furthermore, a real one side process is thereby provided, whereby a subsequent polishing of the substrate backside is omitted. The plasma source is preferably a linear plasma source, that is to say a plasma source extending over the device width. It is thereby possible to simultaneously use wide substrate carriers with a plurality of substrates in the device according to the invention and thus to simultaneously texture a plurality of substrates. In an alternative embodiment of the invention, the plasma source can also be provided as a high frequency plasma source.

In an advantageous embodiment of the device according to the invention, a substrate tempering device is provided in the plasma etching room. This can be provided, for instance, as a circulation-heater-cooler and can be used for cooling and/or heating of the substrate in order to produce, for instance, a reaction temperature for the texturing process of less than 200° C., preferably of less than 150° C., particularly preferably of less than 100° C. at the substrate surface in the plasma. Alternatively, the substrate may also be heated with the substrate tempering device as needed. Therefore, it is possible to heat the substrate or substrates by using the substrate tempering device in such a way that impurities on the substrate or the substrates, respectively, can be removed by sublimation. The substrate tempering device in the present invention can also be provided as a pure substrate cooling device. Through the use of a substrate cooling device, a good texturing of the substrate surface and at the same time a reduced material abrasion of the silicon substrate can be provided.

In a further embodiment, the device according to the invention is a through-feed or inline device with a substrate transport device running through the plasma etching room for the at least one silicon substrate to be textured. Hence, it is possible to continuously equip the installation with silicon wafers, which enables a timely and energetically more efficient mode of operation than a so-called “batch-method.”

Other features which are considered as characteristic for the invention are set forth in the appended claims.

Although the invention is illustrated and described herein as embodied in a method and a device for texturing a silicon surface, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a diagrammatic, cross-sectional view of an embodiment of the device according to the invention with a fluorine gas source, a sulfur oxide source, an inert gas source, an oxygen source and a microwave plasma source;

FIG. 2 is a cross-sectional view of an alternative embodiment of the device according to the invention with a fluorine gas source in the form of a fluorine gas generating system, a sulfur oxide source, an inert gas source, an oxygen source and a microwave plasma source;

FIG. 3 is a cross-sectional view of an alternative embodiment of the device according to the invention with a fluorine gas source, a sulfur oxide source, an inert gas source, an oxygen source and an ICP source; and

FIG. 4 is a flow diagram showing a possible process sequence of the method according to the invention.

### DETAILED DESCRIPTION OF THE INVENTION

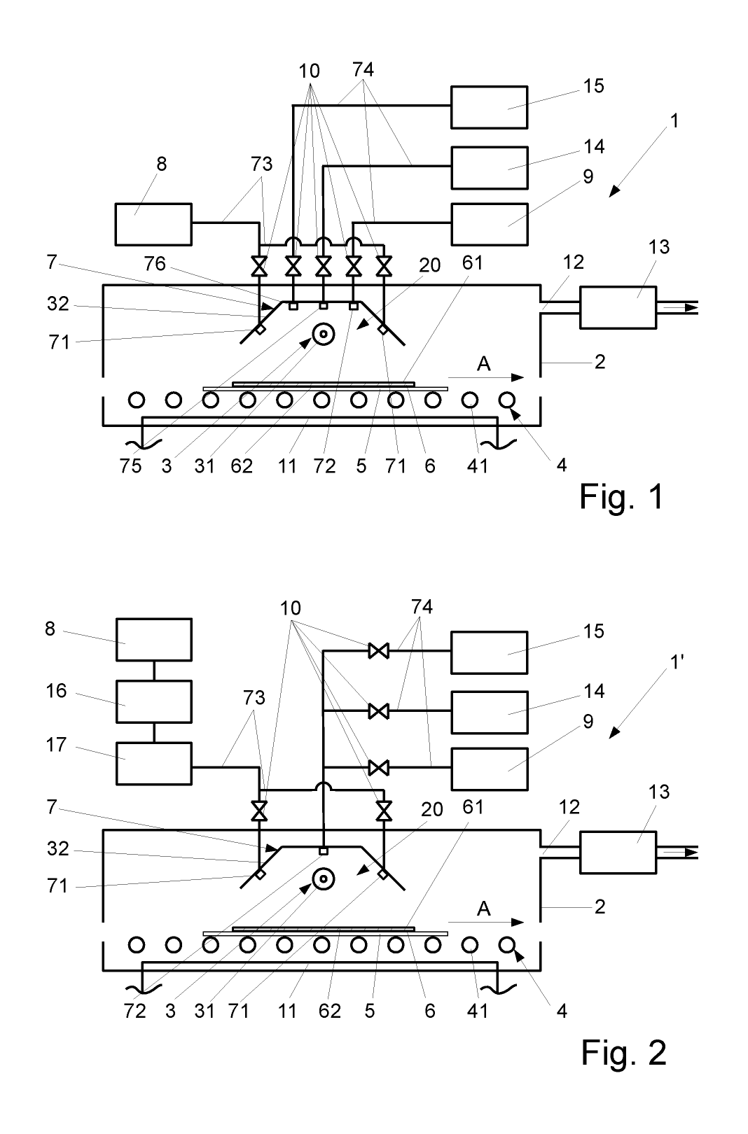

Referring now to the figures of the drawings in detail and first, particularly, to FIG. 1 thereof, there is seen a diagrammatic cross section of a device 1 according to the invention for texturing a substrate surface 61 of at least one silicon substrate 6. The device 1 is preferably, and as illustrated in the embodiments is shown, as a through-feed or inline device, through which the silicon substrate or substrates 6 to be processed is or are passed through during a running texturing process in the device 1.

The exemplary device 1 shown as an example in FIG. 1 includes a plasma etching room or chamber 2, in which a plasma source 3 is provided in an upper part of the plasma etching room 2. In alternative, non-illustrated embodiments, the plasma source 3 can also be provided in a lower part of the plasma etching room 2 or several plasma sources 3 can be provided, which are disposed in a lower as well as in an upper part of the plasma etching room 2.

The plasma source 3 is a microwave plasma source in FIGS. 1 and 2. The microwave plasma source is provided as a tube 31 with an internal antenna in the embodiments shown, in which electromagnetic radiation in the microwave range is generated. The tube 31 is elongated and extends into the image plane of FIG. 1. A standing wave is preferably generated in the tube 31. A gas inlet cap 32, which is disposed adjacent the tube 31, confines the tube 31 on three sides against the plasma etching room 2, whereas a side directed towards the substrate surface 61 remains open. There are no points of contact between the tube 31 and the gas inlet cap 32 in a particularly preferred embodiment. A plasma 20 is generated in the plasma etching room 2 by using the plasma source 3.

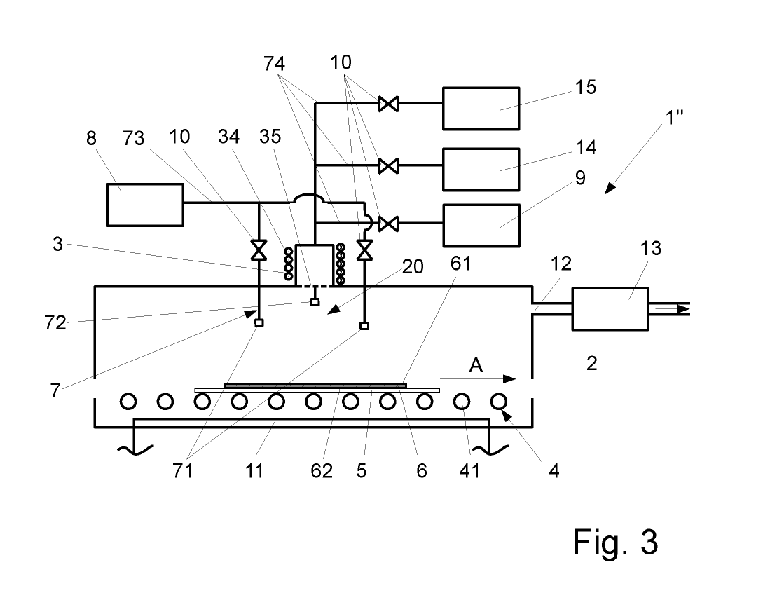

In an alternative embodiment of the device according to the invention, the plasma source 3 may be an ICP source, as shown in FIG. 3. In other, non-illustrated embodiments of the present invention, a plasma source 3 operating in the high frequency range can also be used instead of the microwave plasma source.

In the device 1 according to the invention, several plasma sources in the figures shown can be disposed side by side in the direction running into the image plane as well as below a substrate transport device 4 vertical to a substrate transport direction A. Thereby, for instance, one or several plasma sources 3 may be an ICP source, while at least one further plasma source 3 is a microwave plasma source.

In the embodiment shown in FIG. 1, the substrate transport device 4 is provided in a lower part of the plasma etching room 2 of the device 1. In the embodiment shown, the substrate transport device 4 includes transport rolls 41, on which a substrate carrier 5 in a substrate transport direction A and/or opposite to this substrate transport direction A is transportable through the plasma etching room 2. The transport rolls 41 run into the image plane of FIG. 1. In other, non-illustrated embodiments of the present invention, the substrate transport device 4 may also include other transport mechanisms than the transport rolls 41 shown such as at least one conveyor belt or the substrate carrier 5 may be movable along running rails.

The at least one silicon substrate 6, having the substrate surface 61 to be textured in the process, is provided on the substrate carrier 5 during a texturing process carried out in the device 1. The silicon substrate 6 shown in the embodiments of FIGS. 1 to 3 is thereby transported through the plasma etching room 2 on the substrate carrier 5 with its surface 61 to be textured facing upwards. The substrate surface 61 on the front, which is exposed to the plasma 20, can thereby be textured, while a substrate backside 62 of the substrate 6, which is provided on the carrier 5, is not exposed to the plasma 20.

The supply of the respective gas components into the plasma etching room 2 is provided by a gas inlet device 7. The gas inlet device 7 includes gas inlets 71 connected to a fluorine source 8 as well as a gas inlet 72 connected to a sulfur oxide source 9. The gas inlets 71 are connected to the fluorine source 8 by a gas transmission system 73. The gas inlet 72 is connected to the sulfur oxide source 9 by a gas line 74. As shown in FIG. 1, further gas inlets 75 and 76, which are connected with an argon source 14 and an oxygen source 15 by gas lines 74, open out into the plasma etching room 2. A mass flow controller 10 is respectively provided in the gas lines 73 and 74. Pressure reducing valves can also be used instead of the mass flow controllers 10. In an alternative embodiment, as is shown in FIG. 2, for instance, process and auxiliary gases such as sulfur oxide, oxygen and/or argon can also be premixed and can be passed together into the plasma etching room 2. The delivery of the fluorine gas to the plasma etching room 2 is preferably provided separately from the other process and auxiliary gases.

The gas inlets 71, 72, 75, 76 extend over the width of the device 1 in the embodiment shown, that is in FIGS. 1 to 3, over into the image plane. The gas inlets 71, 72, 75, 76 can be provided in the form of tubes or, for instance, square profiles. Along this longitudinal extension, the gas inlets 71, 72, 75, 76 include openings, from which the respective gas or gas mixture can flow into the plasma etching room 2 and particularly to the substrate surface 61.

In the embodiments shown, the gas inlets 71, 72, 75, 76 are provided at the funnel-shaped gas inlet cap 32 provided above the silicon substrate 6 to be textured. Thereby, the gas inlets 71 are disposed at a lateral inner wall of the gas inlet cap 32 and the gas inlets 72, 75, 76 at an upper inner wall of the gas inlet cap 32.

A substrate tempering device 11 is provided in the plasma etching room 2. However, temperatures of more than 180° C., which are often generated in the plasma 20, are unfavorably high for the texturing process. Thus, the substrate tempering device 11 is provided in such a way that the silicon substrate 6 and/or the substrate surface 61 in the plasma 20 can be cooled to temperatures of less than 200° C., preferably of less than 150° C., particularly preferred of less than 100° C. For instance, the substrate tempering device 11, as is diagrammatically shown in FIGS. 1 to 3, can be provided in form of a fluid cooling device disposed below the substrate transport device 4. Alternatively, other embodiments are applicable, for instance, a tempering medium can directly flow through the transport rolls 41. However, the substrate tempering device 11 can also basically be used for heating the interior of the plasma etching room 2 and/or of the substrate or substrates.

A gas outlet 12, which is provided at the plasma etching room 2, opens out into a wet chemical exhaust gas treatment device 13. Thus, process and auxiliary gases not used during the texturing process as well as gases resulting from the texturing process can be discharged by the gas outlet 12 from the plasma etching room 2. In other embodiments of the present invention, several gas outlets 12 can also be provided.

In the exhaust gas treatment device 13, toxic, environmentally harmful and/or acidic reacting gases are wet chemically adsorbed and/or absorbed. For example, fluorine, sulfur dioxide, silicon tetrafluoride, hydrogen fluoride, oxygen difluoride and/or further gases are among the gases which need to be separated from the exhaust gases. Some or all of these gases can enter into chemical reactions in the exhaust gas treatment device 13 so that they are transformed into other, less hazardous substances. Thereby resulting or already present acidic reacting substances such as hydrofluoric acid, also known as hydrogen fluoride, can be neutralized by adding at least one base in order to obtain safe waste.

A possible embodiment is shown in FIG. 1, in which each gas source 8, 9, 14, 15 is respectively connected with one or several separate gas inlets 71, 72. 75, 76. Alternatively, an embodiment of the device 1′ according to the invention is shown in FIG. 2, in which the gas lines 74, which extend from the sulfur oxide source 9, the argon source 14 and the oxygen source 15, are connected prior to an introduction of the gas into the plasma etching room 2 through the gas inlet 72. Thus, in the device 1′ of FIG. 2, sulfur oxide, argon and oxygen are introduced by a joint gas inlet 72 into the plasma etching room 2. In other, non-illustrated embodiments of the present invention, two or more of the process gases being used can be mixed before their delivery to the gas inlet 72.

In the device 1′ shown in FIG. 2, the fluorine source 8 is provided as fluorine gas generating system. The fluorine gas generating system is connected to a cleaning module 16 and to a pressure raising device 17 in the embodiment shown. Electrolysis of hydrogen fluoride is performed in the fluorine gas generating system, by which fluorine gas and hydrogen gas are formed. In order to produce fluorine gas of high purity, the cleaning module 16 is provided after the fluorine gas generating system. A separation of the fluorine gas from the other exhaust gases can be carried out in the cleaning module 16. After the cleaning module 16, the pressure raising device 17 is provided, which may include a compressor and/or a pressure vessel, for instance.

In FIG. 3, a further embodiment of the device 1″ according to the invention is shown, at which an ICP source as plasma source 3 produces the plasma 20 in the plasma etching room 2. In this case, the gas lines 74 extending from the sulfur oxide source 9, the argon source 14, and the oxygen source 15 also lead into a gas inlet 72 in the plasma etching room 2. The plasma source 3 is provided above the plasma etching room 2. The plasma source 3 includes a coil 34, having a magnetic field which is coupled into the plasma etching room 2 by a dielectric window 35, which may be formed of ceramics, glass or quartz, for instance, in order to provide therein atoms and/or molecules to ionize the gases therein and thus, to produce the plasma 20. The gas inlets 71 for the fluorine gas are disposed more closely at the substrate surface 61 than the gas inlet 72 for the further process and auxiliary gases. Hence, the fluorine gas mixes in the plasma only just above the substrate surface 61 with the further process and auxiliary gases.

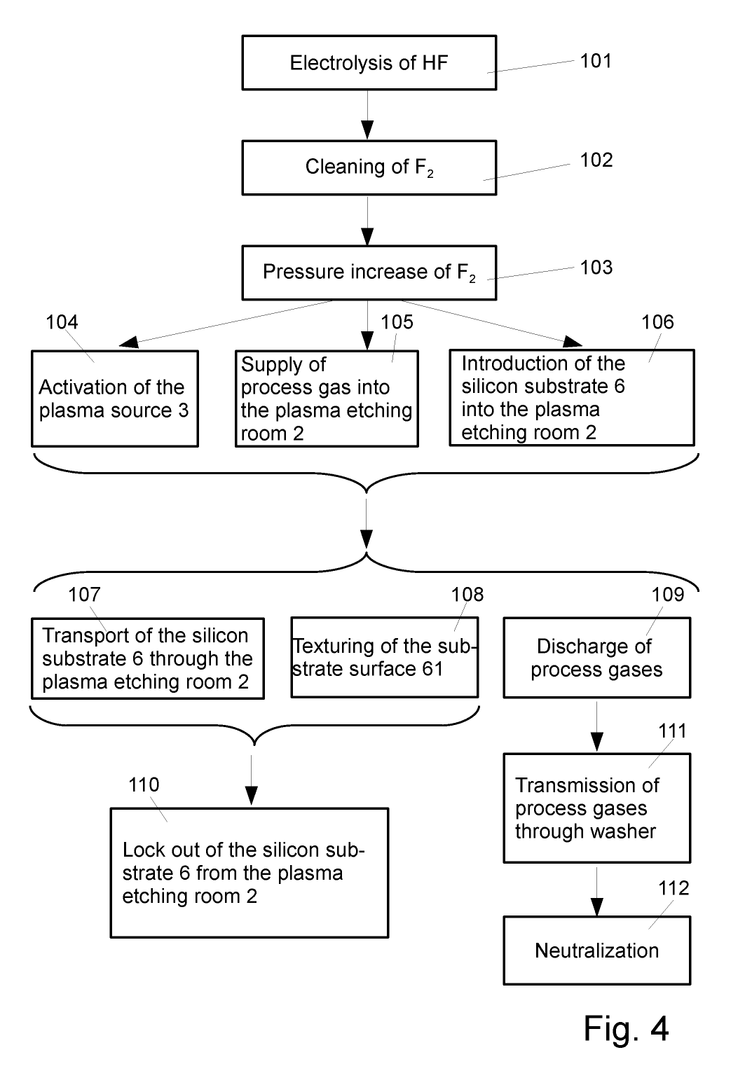

An embodiment of a texturing method operable by the device 1, 1′, 1″ is shown in FIG. 4. In the method according to the invention, fluorine gas and at least sulfur oxide are used as process gases for the texturing of the crystalline silicon substrate 6. Furthermore, an inert gas, for instance, argon is used as a further process gas. The inert gas thereby works as a stabilizing medium for the plasma 20. Moreover, as mentioned in the embodiments described above, oxygen, for instance, may be supplied as a further process gas into the plasma etching room or chamber 2.

In a step 101 of the method example of FIG. 4, the fluorine gas (F₂) is produced by electrolysis of hydrogen fluoride (HF) in a fluorine gas generating system. Subsequently, the fluorine gas is cleaned in a step 102 and is put under pressure in a step 103. Before, after or simultaneously with the activation of the plasma source 3 in a step 104, the process and auxiliary gases such as fluorine, sulfur oxide, oxygen and argon, are led into the plasma etching room 2 in a step 105. Parallel or as a follow-up to this, the at least one silicon substrate 6 is introduced into the plasma etching room 2 in a step 106.

Thereupon, the at least one silicon substrate 6 is transported continuously through the plasma etching room 2 in the substrate transport direction A by using the substrate transport device 4 in a step 107 in the embodiments shown. The texturing of the substrate surface 61 is carried out in a step 108 during the transport of the at least one silicon substrate 6 through the plasma etching room 2.

The proportion of the process gases as well as the process temperature is crucial for an effective texturing. Expressed in volume percent, according to the invention 30% to 90%, preferably 40% to 80%, particularly preferably 50% to 70% of fluorine gas are used. 5% to 55%, preferably 15% to 45%, particularly preferably 25% to 35% of sulfur oxide are used. All compounds of the general chemical formula SₓO_{y} such as disulfur monoxide, sulfur monoxide, sulfur dioxide, disulfur dioxide or sulfur trioxide are classified as sulfur oxide. Particularly preferred is the usage of sulfur dioxide. A plasma stabilizing inert gas, particularly preferably argon, of 1% to 25%, preferably 5% to 20%, particularly preferably 10% to 15% is added to the process according to the invention. Oxygen is used in the process in amounts less than 50%, preferably less than 20%, particularly preferably less than 10%. It has thereby been shown that the polymer deposition on the at least one silicon substrate 6 to be textured can be reduced when using oxygen. It has been thereby proven particularly advantageous if oxygen is not continuously added uniformly over the entire process sequence, but if the oxygen percentage is increased preferably towards the end of the process.

This mixture of gases, which is introduced as mentioned above by the gas inlet device 7 at a resulting pressure of less than 100 mbar, particularly preferably of less than 10 mbar into the plasma etching room 2, is ignited by at least one suitable plasma source 3 into a plasma 20. The thus formed particles such as radicals, ions as well as atoms and molecules in excited states react subsequently with the silicon substrate 6 and lead to a texturing of the substrate surface 61. In such a plasma 20, high temperatures, being dependent on the chosen gas mixture as well as the chosen plasma source 3 and the prevailing pressure, often dominate in the plasma 20. It has been found that the results of the texturing can be optimized if a substrate tempering device 11, which is particularly provided as a substrate cooling device, is provided for the silicon substrate 6. Thus, reaction temperatures of less than 200° C., preferably of less than 150° C., particularly preferably of less than 100° C. can be realized on the substrate surface 61.

Through the use of the method according to the invention, at the substrate surface 61, textures with a texture size of less than 20 μm, particularly of less than 10 μm and particularly preferably of less than 1 μm can be generated on silicon substrates 6. In this context, texture size means the scale of the structures, which are evoked by the texturing on the substrate surface 61. If pyramids or inverse pyramids are used as structure elements, the texture size means, for instance, a height or an edge length of the pyramids. In the case of spongy or other less regular structure elements, the texture size means, for instance, a pore size, a distance of profile points of the same height in a height profile of the substrate surface 61 or the like.

In the method according to the invention, an etching rate of less than 5 μm/min, particularly of less than 1 μm/min can be set, whereby a controlled, material friendly texturing is possible, that is a specific abrasion of less than 5 μm, particularly preferably of less than 2 μm material. Due to the provision of textures resulting from the method according to the invention, solar cells can be produced, for instance, which include an excellently weighted reflectivity value in a wavelength range of 300 nm to 1200 nm, which is smaller than 20%, particularly smaller than 15%, particularly preferably approximately 12%. The weighted reflectivity is known to be normalized to the efficiency of certain wavelengths or respectively to wavelength ranges for the generation of charge carriers in silicon.

During the texturing in a step 109, a continuous outlet of the process gases is carried out. In the method embodiment of FIG. 4, the exhaust gases in a step 111 are directed through a washer, in which, for instance, fluorine gas is transformed into hydrofluoric acid. The hydrofluoric acid as well as further possibly resulting acids are subsequently neutralized in a step 112 by adding at least one base.

According to a step 110, a lock out of the silicon substrate 6 from the plasma etching room 2 is finally carried out.

1. A method for texturing at least one substrate surface of at least one crystalline silicon substrate by etching the at least one substrate surface with fluorine gas, the method comprising the following steps:
etching the silicon substrate in a plasma produced in a plasma etching room; and
supplying the plasma etching room with at least gaseous sulfur oxide in addition to the fluorine gas.

2. The method according to claim 1, which further comprises producing the fluorine gas by electrolysis in at least one fluorine gas generating system coupled with the plasma etching room, and supplying the fluorine gas into the plasma etching room.

3. The method according to claim 1, which further comprises introducing the fluorine gas into the plasma etching room closer to the substrate surface than other process gases used in the method.

4. The method according to claim 1, which further comprises discharging process gases not used during etching and exhaust gases resulting from etching from the plasma through at least one gas outlet, and subsequently passing the process gases not used during etching and exhaust gases resulting from etching through at least one wet chemical exhaust gas treatment device.

5. The method according to claim 1, which further comprises producing the plasma at least one of at a frequency in the microwave range or by using at least one inductively coupled plasma source.

6. The method according to claim 1, which further comprises tempering the silicon substrates in the plasma etching room by using a substrate tempering device.

7. The method according to claim 1, which further comprises continuously transporting the silicon substrates on a substrate transport device through the plasma etching room.

8. A device for texturing at least one substrate surface of at least one crystalline silicon substrate, the device comprising:
a plasma etching room for receiving the at least one crystalline silicon substrate;
at least one plasma source leading to said plasma etching room;
a fluorine source;
at least one sulfur oxide source; and
a gas inlet device coupled to said fluorine source, additionally coupled to said at least one sulfur oxide source and leading to said plasma etching room.

9. The device according to claim 8, wherein said fluorine source is coupled to said plasma etching room and is at least one of a fluorine gas supply system or a fluorine gas generating system, in which fluorine is producible by electrolysis from hydrogen fluoride before its supply into said plasma etching room.

10. The device according to claim 8, wherein said gas inlet device includes a gas inlet connected to said fluorine source and a gas inlet connected to said sulfur oxide source, said gas inlet connected to said fluorine source being disposed closer to the substrate surface than said gas inlet connected to said sulfur oxide source.

11. The device according to claim 8, which further comprises at least one wet chemical exhaust gas treatment device, said plasma etching room including at least one gas outlet opening out into said least one wet chemical exhaust gas treatment device.

12. The device according to claim 8, wherein said at least one plasma source is at least one of a microwave plasma source or an inductively coupled plasma source.

13. The device according to claim 8, which further comprises at least one substrate tempering device provided in said plasma etching room.

14. The device according to claim 8, wherein the device is a through-feed or inline device having a substrate transport device running through said plasma etching room for transporting the at least one silicon substrate to be textured.
